(19) United States
(12) Patent Application Publication
(10) Pub. No.: US 2026/0361286 A1
(43) Pub. Date: Nov. 12, 2026

(54) ACOUSTIC WAVE DEVICE WITH CAVITY IN SUPPORT SUBSTRATE

(71) Applicant: Skyworks Solutions, Inc., Irvine, CA (US)

(72) Inventors: David Albert Feld, Los Altos, CA (US); Rei Goto, Osaka-Shi (JP)

(21) Appl. No.: 19/644,868

(22) Filed: Apr. 10, 2026

Related U.S. Application Data
(60) Provisional application No. 63/788,952, filed on Apr. 15, 2025.
(60) Provisional application No. 63/789,006, filed on Apr. 15, 2025.
(60) Provisional application No. 63/788,983, filed on Apr. 15, 2025.
(60) Provisional application No. 63/788,989, filed on Apr. 15, 2025.

(51) Int. Cl. H03H 9/02; H03H 9/05; H03H 9/25; H03H 9/52; H03H 9/64

(52) U.S. Cl. CPC H03H 9/02574; H03H 9/02007; H03H 9/02661; H03H 9/058; H03H 9/25; H03H 9/52; H03H 9/64

(57) ABSTRACT

A surface acoustic wave device is disclosed. The surface acoustic wave device can include a support substrate having a cavity, a piezoelectric layer over the support substrate, and an interdigital transducer electrode in electrical communication with the piezoelectric layer. The interdigital transducer electrode is positioned over the cavity. The support substrate can be part of a multi-layer piezoelectric substrate including the support substrate, a piezoelectric layer over the support substrate, and an intermediate structure between the support substrate and the piezoelectric layer.

### INCORPORATION BY REFERENCE TO ANY PRIORITY APPLICATIONS

This application is a non-provisional application that claims the benefit of U.S. Provisional Patent Application No. 63/788,952, filed Apr. 15, 2025, titled “ACOUSTIC WAVE DEVICE WITH CAVITY IN SUPPORT SUBSTRATE,” U.S. Provisional Patent Application No. 63/789,006, filed Apr. 15, 2025, titled “MULTILAYER PIEZOELECTRIC SUBSTRATE ACOUSTIC WAVE DEVICE WITH INTERMEDIATE STRUCTURE HAVING CAVITY,” U.S. Provisional Patent Application No. 63/788,983, filed Apr. 15, 2025, titled “ACOUSTIC WAVE DEVICE WITH CAVITY STRUCTURE IN SUPPORT STRUCTURE,” and U.S. Provisional Patent Application No. 63/788,989, filed Apr. 15, 2025, titled “MULTILAYER PIEZOELECTRIC SUBSTRATE ACOUSTIC WAVE DEVICE WITH NON-PERIODICALLY PATTERNED CAVITY STRUCTURE,” the entireties of which are hereby incorporated by reference herein and made a part of the present disclosure. Any and all applications for which a foreign or domestic priority claim is identified in connection with the present application are hereby incorporated by reference under 37 C.F.R. § 1.57 in their entirety herein and made a part of the present disclosure.

### BACKGROUND

### Technical Field

Embodiments of this disclosure relate to multilayer piezoelectric substrate (MPS) acoustic wave devices with a cavity in the MPS.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transducer electrode on a piezoelectric substrate. The surface acoustic wave resonator can generate a surface acoustic wave on a surface of the piezoelectric layer on which the interdigital transducer electrode is disposed.

There can be unwanted responses generated in a SAW device, including nonlinearity, which distorts the signal by producing harmonics, intermodulation products, and spurious signals not present in the original input. These effects degrade device performance by reducing signal fidelity and creating interference. In high-precision applications like telecommunications and signal processing, minimizing nonlinearity is crucial to maintain optimal performance, making it a key design goal for SAW devices.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a surface acoustic wave device including: a support substrate having a cavity; a piezoelectric layer over the support substrate; and an interdigital transducer electrode in electrical communication with the piezoelectric layer and being positioned over the cavity.

In some embodiments, the techniques described herein relate to a surface acoustic wave device wherein an area of the cavity is greater than an area of the interdigital transducer electrode.

In some embodiments, the techniques described herein relate to a surface acoustic wave device wherein the cavity is one of patterned cavities.

In some embodiments, the techniques described herein relate to a surface acoustic wave device wherein the patterned cavities are aligned with fingers of the interdigital transducer electrode.

In some embodiments, the techniques described herein relate to a surface acoustic wave device wherein the patterned cavities are aligned with gaps between fingers of the interdigital transducer electrode.

In some embodiments, the techniques described herein relate to a surface acoustic wave device wherein the patterned cavities have a non-periodic pattern.

In some embodiments, the techniques described herein relate to a surface acoustic wave device wherein the patterned cavities have an aperiodic pattern.

In some embodiments, the techniques described herein relate to a surface acoustic wave device wherein the cavity includes an air cavity.

In some embodiments, the techniques described herein relate to a surface acoustic wave device wherein the cavity is at least partially filled with a dielectric material.

In some embodiments, the techniques described herein relate to a surface acoustic wave device further including a second interdigital transducer electrode in electrical communication with the piezoelectric layer.

In some embodiments, the techniques described herein relate to a surface acoustic wave device further including a second cavity, wherein the second interdigital transducer electrode is positioned over the second cavity.

In some embodiments, the techniques described herein relate to a surface acoustic wave device wherein the second cavity is formed in the support substrate.

In some embodiments, the techniques described herein relate to a surface acoustic wave device further including an intermediate structure between the support substrate and the piezoelectric layer.

In some aspects, the techniques described herein relate to a surface acoustic wave device including: a multi-layer piezoelectric substrate including a support substrate, a piezoelectric layer over the support substrate, and an intermediate structure between the support substrate and the piezoelectric layer, the support substrate having an air cavity; and an interdigital transducer electrode in electrical communication with the piezoelectric layer and being positioned over the air cavity.

In some embodiments, the techniques described herein relate to a surface acoustic wave device wherein the intermediate structure includes a trap-rich layer and a dielectric layer.

In some aspects, the techniques described herein relate to an acoustic wave filter including: a support substrate having a cavity; a piezoelectric layer over the support substrate; a first acoustic wave element including an interdigital transducer electrode in electrical communication with the piezoelectric layer and being positioned over the cavity; and a second acoustic wave element electrically coupled to the first acoustic wave element.

In some embodiments, the techniques described herein relate to an acoustic wave filter wherein the second acoustic wave element is a surface acoustic wave resonator.

In some embodiments, the techniques described herein relate to an acoustic wave filter wherein the second acoustic wave element is a bulk acoustic wave resonator.

In some embodiments, the techniques described herein relate to an acoustic wave filter further including an intermediate structure between the support substrate and the piezoelectric layer.

In some embodiments, the techniques described herein relate to an acoustic wave filter wherein the intermediate structure includes a second cavity.

In some aspects, the techniques described herein relate to a surface acoustic wave device including: a support structure including a support substrate, a first intermediate layer over the support substrate, and a second intermediate layer over the first intermediate layer, the first intermediate layer having a cavity; a piezoelectric layer over the second intermediate layer; and an interdigital transducer electrode in electrical communication with the piezoelectric layer and being positioned over the cavity.

In some embodiments, the techniques described herein relate to a surface acoustic wave device wherein the second intermediate layer has a higher temperature coefficient of elasticity than the first intermediate layer.

In some embodiments, the techniques described herein relate to a surface acoustic wave device wherein the first intermediate layer includes polycrystalline silicon.

In some embodiments, the techniques described herein relate to a surface acoustic wave device wherein the first intermediate layer is in contact with the support substrate.

In some embodiments, the techniques described herein relate to a surface acoustic wave device wherein an area of the cavity is greater than an area of the interdigital transducer electrode.

In some embodiments, the techniques described herein relate to a surface acoustic wave device wherein the cavity is one of patterned cavities.

In some embodiments, the techniques described herein relate to a surface acoustic wave device wherein the patterned cavities are aligned with fingers of the interdigital transducer electrode.

In some embodiments, the techniques described herein relate to a surface acoustic wave device wherein the patterned cavities are aligned with gaps between fingers of the interdigital transducer electrode.

In some embodiments, the techniques described herein relate to a surface acoustic wave device wherein the patterned cavities have a non-periodic pattern.

In some embodiments, the techniques described herein relate to a surface acoustic wave device wherein the patterned cavities have an aperiodic pattern.

In some embodiments, the techniques described herein relate to a surface acoustic wave device wherein the cavity includes an air cavity.

In some embodiments, the techniques described herein relate to a surface acoustic wave device wherein the cavity is at least partially filled with a dielectric material.

In some embodiments, the techniques described herein relate to a surface acoustic wave device wherein the cavity includes an air gap.

In some aspects, the techniques described herein relate to a surface acoustic wave device including: a multi-layer piezoelectric substrate including a support substrate, a piezoelectric layer over the support substrate, and an intermediate structure between the support substrate and the piezoelectric layer, the intermediate structure having a trap-rich layer with a cavity and a dielectric layer positioned between the trap-rich layer and the piezoelectric layer; and an interdigital transducer electrode in electrical communication with the piezoelectric layer and being positioned over the cavity.

In some embodiments, the techniques described herein relate to a surface acoustic wave device wherein the trap-rich layer includes polycrystalline silicon and the dielectric layer includes silicon oxide.

In some aspects, the techniques described herein relate to an acoustic wave filter including: a support structure including a support substrate, a first intermediate layer over the support substrate, and a second intermediate layer over the first intermediate layer, the first intermediate layer having a cavity; a piezoelectric layer over the support structure; a first acoustic wave element including an interdigital transducer electrode in electrical communication with the piezoelectric layer and being positioned over the cavity; and a second acoustic wave element electrically coupled to the first acoustic wave element.

In some embodiments, the techniques described herein relate to an acoustic wave filter wherein the second acoustic wave element is a surface acoustic wave resonator.

In some embodiments, the techniques described herein relate to an acoustic wave filter wherein the second acoustic wave element is a bulk acoustic wave resonator.

In some embodiments, the techniques described herein relate to an acoustic wave filter wherein the support structure further includes a second cavity.

In some embodiments, the techniques described herein relate to an acoustic wave filter wherein the first intermediate layer includes polycrystalline silicon, and the second intermediate layer has a higher temperature coefficient of elasticity than the first intermediate layer.

In some embodiments, the techniques described herein relate to a surface acoustic wave device including: a support structure including a patterned cavity structure; a piezoelectric layer over the support structure; and an interdigital transducer electrode in electrical communication with the piezoelectric layer and being positioned over the patterned cavity structure.

In some embodiments, the techniques described herein relate to a surface acoustic wave device wherein an area of the patterned cavity structure is greater than an area of the interdigital transducer electrode.

In some embodiments, the techniques described herein relate to a surface acoustic wave device wherein cavities of the patterned cavity structure are aligned with fingers of the interdigital transducer electrode.

In some embodiments, the techniques described herein relate to a surface acoustic wave device wherein cavities of the patterned cavity structure are aligned with gaps between fingers of the interdigital transducer electrode.

In some embodiments, the techniques described herein relate to a surface acoustic wave device wherein the patterned cavity structure has a non-periodic pattern.

In some embodiments, the techniques described herein relate to a surface acoustic wave device wherein the patterned cavity structure has an aperiodic pattern.

In some embodiments, the techniques described herein relate to a surface acoustic wave device wherein the patterned cavity structure includes an air cavity.

In some embodiments, the techniques described herein relate to a surface acoustic wave device wherein the patterned cavity structure is at least partially filled with a dielectric material.

In some embodiments, the techniques described herein relate to a surface acoustic wave device further including a second interdigital transducer electrode in electrical communication with the piezoelectric layer.

In some embodiments, the techniques described herein relate to a surface acoustic wave device further including a second cavity structure, wherein the second interdigital transducer electrode is positioned over the second cavity structure.

In some embodiments, the techniques described herein relate to a surface acoustic wave device wherein the support structure includes a support substrate, a first intermediate layer over the support substrate, and a second intermediate layer over the first intermediate layer.

In some embodiments, the techniques described herein relate to a surface acoustic wave device wherein the patterned cavity structure is formed in the support substrate.

In some embodiments, the techniques described herein relate to a surface acoustic wave device wherein the patterned cavity structure is formed in the first intermediate layer.

In some embodiments, the techniques described herein relate to a surface acoustic wave device wherein the patterned cavity structure is formed in the second intermediate layer.

In some embodiments, the techniques described herein relate to a surface acoustic wave device wherein the second intermediate layer has a higher temperature coefficient of elasticity than the first intermediate layer.

In some embodiments, the techniques described herein relate to a surface acoustic wave device wherein the first intermediate layer includes polycrystalline silicon.

In some aspects, the techniques described herein relate to a surface acoustic wave device including: a support structure including a support substrate, a first intermediate layer over the support substrate, a second intermediate layer over the first intermediate layer, and a patterned cavity structure; a piezoelectric layer over the support structure; and an interdigital transducer electrode in electrical communication with the piezoelectric layer and being positioned over the patterned cavity structure.

In some embodiments, the techniques described herein relate to a surface acoustic wave device wherein the patterned cavity structure includes cavities that are aligned with fingers of the interdigital transducer electrode or aligned with gaps between fingers of the interdigital transducer electrode.

In some aspects, the techniques described herein relate to an acoustic wave filter including: a support structure having a patterned cavity structure; a piezoelectric layer over the support structure; a first acoustic wave element including an interdigital transducer electrode in electrical communication with the piezoelectric layer and being positioned over the patterned cavity structure; and a second acoustic wave element electrically coupled to the first acoustic wave element.

In some embodiments, the techniques described herein relate to an acoustic wave filter wherein the support structure includes a support substrate, a first intermediate layer over the support substrate, and a second intermediate layer over the first intermediate layer.

In some aspects, the techniques described herein relate to a surface acoustic wave device including: a support structure including a support substrate, a first intermediate layer over the support substrate, and a second intermediate layer over the first intermediate layer, the first intermediate layer having a non-periodically patterned cavity structure; a piezoelectric layer over the support structure; and an interdigital transducer electrode in electrical communication with the piezoelectric layer and being positioned over the non-periodically patterned cavity structure.

In some embodiments, the techniques described herein relate to a surface acoustic wave device wherein the non-periodically patterned cavity structure has an aperiodic pattern.

In some embodiments, the techniques described herein relate to a surface acoustic wave device wherein an area of the non-periodically patterned cavity structure is greater than an area of the interdigital transducer electrode.

In some embodiments, the techniques described herein relate to a surface acoustic wave device wherein the non-periodically patterned cavity structure includes an air cavity.

In some embodiments, the techniques described herein relate to a surface acoustic wave device wherein the non-periodically patterned cavity structure is at least partially filled with a dielectric material.

In some embodiments, the techniques described herein relate to a surface acoustic wave device further including a second interdigital transducer electrode in electrical communication with the piezoelectric layer.

In some embodiments, the techniques described herein relate to a surface acoustic wave device further including a second cavity structure, wherein the second interdigital transducer electrode is positioned over the second cavity structure.

In some embodiments, the techniques described herein relate to a surface acoustic wave device wherein the support structure includes a support substrate, a first intermediate layer over the support substrate, and a second intermediate layer over the first intermediate layer.

In some embodiments, the techniques described herein relate to a surface acoustic wave device wherein the non-periodically patterned cavity structure is formed in the support substrate.

In some embodiments, the techniques described herein relate to a surface acoustic wave device wherein the non-periodically patterned cavity structure is formed in the first intermediate layer.

In some embodiments, the techniques described herein relate to a surface acoustic wave device wherein the non-periodically patterned cavity structure is formed in the second intermediate layer.

In some embodiments, the techniques described herein relate to a surface acoustic wave device wherein the second intermediate layer has a higher temperature coefficient of elasticity than the first intermediate layer.

In some embodiments, the techniques described herein relate to a surface acoustic wave device wherein the first intermediate layer includes polycrystalline silicon.

In some aspects, the techniques described herein relate to a surface acoustic wave device including: a support structure including a support substrate, a first intermediate layer over the support substrate, a second intermediate layer over the first intermediate layer, and a non-periodically patterned cavity structure; a piezoelectric layer over the support substrate; and an interdigital transducer electrode in electrical communication with the piezoelectric layer and being positioned over the non-periodically patterned cavity structure.

In some embodiments, the techniques described herein relate to a surface acoustic wave device wherein the non-periodically patterned cavity structure includes air cavities.

In some aspects, the techniques described herein relate to an acoustic wave filter including: a support structure having a non-periodically patterned cavity structure; a piezoelectric layer over the support structure; a first acoustic wave element including an interdigital transducer electrode in electrical communication with the piezoelectric layer and being positioned over the non-periodically patterned cavity structure; and a second acoustic wave element electrically coupled to the first acoustic wave element.

In some embodiments, the techniques described herein relate to an acoustic wave filter wherein the support structure includes a support substrate, a first intermediate layer over the support substrate, and a second intermediate layer over the first intermediate layer.

In some embodiments, the techniques described herein relate to an acoustic wave filter wherein the non-periodically patterned cavity structure is formed in the support substrate, the first intermediate layer, or the second intermediate layer.

In some embodiments, the techniques described herein relate to an acoustic wave filter wherein the second acoustic wave element is a surface acoustic wave resonator.

In some embodiments, the techniques described herein relate to an acoustic wave filter wherein the second acoustic wave element is a bulk acoustic wave resonator.

The present disclosure relates to U.S. Patent Application No. ______ [Attorney Docket SKYWV-1607A2], titled “MULTILAYER PIEZOELECTRIC SUBSTRATE ACOUSTIC WAVE DEVICE WITH INTERMEDIATE STRUCTURE HAVING CAVITY,” and U.S. Patent Application No. ______ [Attorney Docket SKYWV-1607A3], titled “ACOUSTIC WAVE DEVICE WITH CAVITY STRUCTURE IN SUPPORT STRUCTURE,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a surface acoustic wave (SAW) device according to an embodiment.

FIG. 1B is a schematic cross-sectional side view of a SAW device according to another embodiment.

FIG. 1C is a schematic cross-sectional side view of a SAW device according to another embodiment.

FIG. 1D is a schematic cross-sectional side view of a SAW device according to another embodiment.

FIG. 2 is a schematic cross-sectional side view of a SAW device according to another embodiment.

FIG. 3 is a schematic cross-sectional side view of a SAW device according to another embodiment.

FIG. 4 is a schematic cross-sectional side view of a SAW device according to another embodiment.

FIG. 5A is a schematic cross-sectional side view of an acoustic wave device according to another embodiment.

FIG. 5B is a schematic top-plan view of the acoustic wave device of FIG. 5A.

FIG. 6A is a schematic cross-sectional side view of an acoustic wave device according to an embodiment.

FIG. 6B is a schematic cross-sectional side view of an acoustic wave device according to another embodiment.

FIG. 7 is a schematic diagram of a radio frequency module that includes a surface acoustic wave resonator according to an embodiment.

FIG. 8 is a schematic diagram of a radio frequency module that includes filters with surface acoustic wave resonators according to an embodiment.

FIG. 9 is a schematic block diagram of a module that includes an antenna switch and duplexers that include a surface acoustic wave resonator according to an embodiment.

FIG. 10A is a schematic block diagram of a module that includes a power amplifier, a radio frequency switch, and duplexers that include a surface acoustic wave resonator according to an embodiment.

FIG. 10B is a schematic block diagram of a module that includes filters, a radio frequency switch, and a low noise amplifier according to an embodiment.

FIG. 11A is a schematic block diagram of a wireless communication device that includes a filter with a surface acoustic wave resonator in accordance with one or more embodiments.

FIG. 11B is a schematic block diagram of another wireless communication device that includes a filter with a surface acoustic wave resonator in accordance with one or more embodiments.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

An acoustic wave system, such as an acoustic wave filter, can include a plurality of acoustic wave devices to process acoustic waves. The acoustic wave devices can include surface acoustic wave devices and/or bulk acoustic wave devices. A multi-band acoustic wave filter is an example of the acoustic wave system and is an electronic device that can selectively filter or pass specific frequency bands in a signal. The multi-band acoustic wave filter can operate at multiple frequency bands to filter and separate different signals. A surface acoustic wave (SAW) filter, a bulk acoustic wave (BAW) filter, and a hybrid acoustic wave filter that includes one or more acoustic wave devices and one or more bulk acoustic wave devices are examples of the multi-band acoustic wave filter.

Acoustic wave filters can filter radio frequency (RF) signals in a variety of applications, such as in an RF front end of a mobile phone. An acoustic wave filter can be implemented with surface acoustic wave (SAW) devices. SAW devices include SAW resonators, SAW delay lines, and multi-mode SAW (MMS) filters (e.g., double-mode SAW (DMS) filters). Although embodiments may be discussed with reference to SAW resonators, the principles and advantages discussed herein can be applied to any suitable SAW device and/or any suitable acoustic wave device.

Acoustic wave filters can include SAW resonators that include a multi-layer piezoelectric substrate. Multi-layer piezoelectric substrates can provide good thermal dissipation characteristics and improved temperature coefficient of frequency (TCF) relative to certain single-layer piezoelectric substrates. For example, a SAW resonator with a piezoelectric layer on a high impedance support substrate, such as silicon, can achieve better temperature coefficient of frequency (TCF) and thermal dissipation compared to a similar device without the high impedance support substrate.

For example, a SAW resonator can include a silicon dioxide (SiO₂) layer, a lithium niobate (LN) piezoelectric layer, an interdigital transducer (IDT) over the LN piezoelectric layer, and a high impedance support substrate (e.g., a silicon substrate) under the LN piezoelectric layer. Such resonators with the high impedance substrate can be beneficial for obtaining a better TCF and/or a better thermal dissipation characteristic than temperature-compensated (TC) SAW resonators that do not include the high impedance substrate structure.

However, SAW resonators that include a piezoelectric layer on certain high impedance support substrates can experience spurious responses that can cause nonlinearity in the frequency response. Reduced nonlinearity can be desirable in some SAW devices as it can affect the performance (e.g., the quality factor) of the SAW devices. Nonlinearity in SAW devices can be the deviation from a proportional relationship between the input signal and the output response, which can result in signal distortion and unwanted harmonics. Improving nonlinearity can enhance the device's performance by reducing signal degradation, maintaining signal integrity, and ensuring high-fidelity transmission, which can be significant in applications like telecommunications and signal processing. Nonlinear behavior can cause higher-order modes, such as third-order harmonics, to appear, which are multiples of the fundamental frequency and further degrade the signal quality in some applications. Therefore, there is a need for nonlinearity improvement in SAW devices to achieve optimal performance and reliable operation in critical applications.

Embodiments disclosed herein relate to SAW devices with a support substrate that prevents or suppresses the formation of the nonlinearity. A SAW device according to embodiments disclosed herein can include a multi-layer piezoelectric substrate (MPS) including a piezoelectric layer and a support structure including a support substrate, and an interdigital transducer (IDT) electrode in electrical communication with the piezoelectric layer. In some embodiments, the support structure in the MPS can also include an intermediate structure having one or more of, for example, a functional layer, a trap-rich layer, or a seed layer. The SAW device can also include a cavity structure in the support structure. The cavity structure can confine acoustic energy between the IDT electrode and the cavity structure or in the piezoelectric layer. The cavity structure can also reduce parasitic surface conductive effects on a surface of the support substrate, in some applications. As a result, the cavity structure can contribute to reducing nonlinearity. The cavity structure can include one or more cavities. The cavity structure can be positioned in any suitable locations in the support structure. For example, the cavity structure can be positioned in the support substrate or in the intermediate structure. The one or more cavities of the cavity structure can be patterned in any suitable manner. For example, the cavities can be patterned periodically or non-periodically (e.g., aperiodically or randomly).

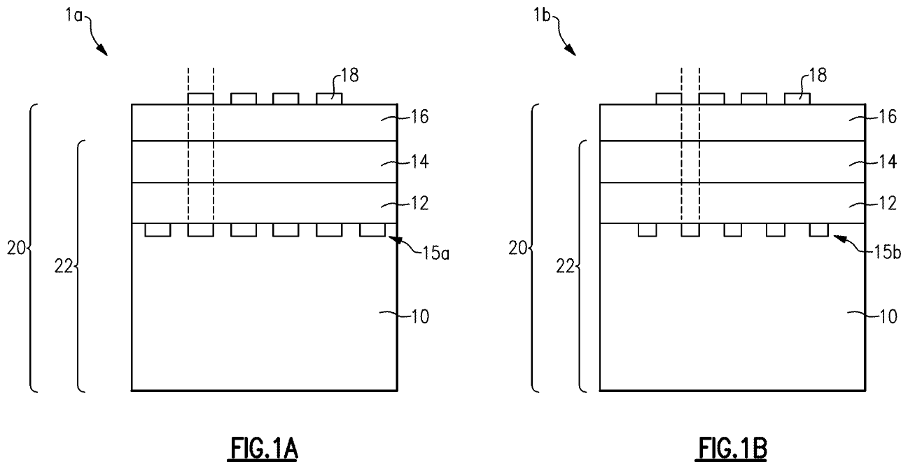

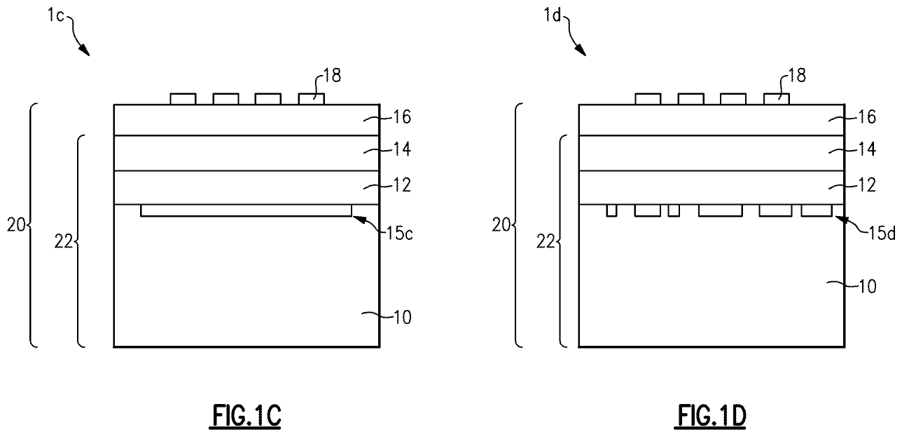

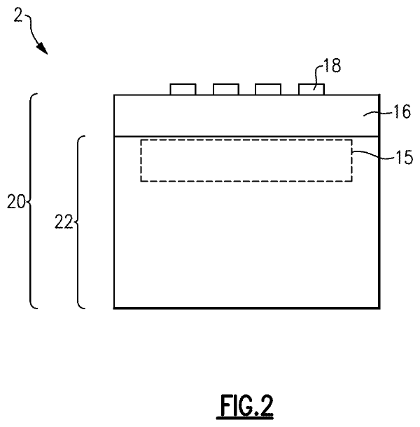

FIG. 1A is a schematic cross-sectional side view of a surface acoustic wave (SAW) device 1a according to an embodiment. The SAW device 1a can be part of a larger system, such as an acoustic wave system (e.g., an acoustic wave filter). The acoustic wave system may include one or more other acoustic wave devices.

The SAW device 1a can include a support substrate 10, a first layer 12, a second layer 14, a cavity structure 15a, a piezoelectric layer 16, and an interdigital transducer (IDT) electrode 18. A multi-layer piezoelectric substrate (MPS) 20 of the SAW device 1a can include the piezoelectric layer 16 and a support structure 22. The support structure 22 can include the support substrate 10, the first layer 12, and the second layer 14.

A cavity structure according to embodiments disclosed herein can be positioned in any suitable location in the support structure 22. In some embodiments, the cavity structure 15a can be positioned in the support substrate 10. For example, the cavity structure 15a can be formed at or near a surface of the support substrate 10 that faces the piezoelectric layer 16.

In some embodiments, the cavity structure 15a can include cavities patterned periodically. For example, a pitch of the cavities can correspond to a pitch of the IDT electrode 18. For example, the cavities can align with fingers of the IDT electrode 18. In some embodiments, a width of a cavity in the cavity structure 15a can be the same as or generally similar to a width of a finger of the IDT electrode 18. The number of cavities in the cavity structure 15a can be equal to, greater than, or less than the number of the fingers in the IDT electrode 18. In some embodiments, an area of the cavity structure 15a can be greater than an area of the IDT electrode 18.

In some embodiments, the cavity structure 15a can be filled with gas. For example, the cavity structure 15a can include an air cavity. In some other embodiments, the cavity structure 15a can be at least partially filled with a dielectric material. The dielectric material can include silicon oxide (e.g., SiO₂), tellurium oxide (e.g., TeO₂), germanium oxide (e.g., GeO₂), tantalum oxide (e.g., Ta₂O₅), silicon nitride (e.g., SiN), silicon oxynitride (e.g., SiON), aluminum nitride (e.g., AlN), silicon carbide (e.g., SiC), or sapphire.

One or more portions of the support substrate 10 between the cavities of the cavity structure 15a can provide mechanical ruggedness. The one or more portions of the support substrate 10 between the cavities of the cavity structure 15a can also provide a heat path. In some embodiments, the cavity structure 15a can be provided in a manner that acoustically isolates the piezoelectric layer 16 from the support structure 22. In such embodiments, a Lamb wave device may be formed. Using the Lamb wave may improve the non-linearity performance of the resonator. The cavity structure 15a may be beneficial for higher frequency applications. When the cavity structure 15a has a relatively thin thickness, the higher order mode may be shifted to a significantly higher frequency as compared to a thicker cavity structure 15a. It can be beneficial for a resonator close to the antenna node (e.g., a resonator closest to the antenna node, a resonator second closest to the antenna node, or a resonator third closest to the antenna node) to maintain signal clarity, stability, or quality. Also, an airgap may be suited for resonators that do not call for power durability, such as a multi-mode SAW (e.g., a double mode surface acoustic wave (DMS) device). While a gas cavity (e.g., the air cavity) or an acoustically isolative layer can be more preferred for Lamb wave and DMS devices and/or receive filter components, including a solid dielectric material or a material that is acoustically non-isolative can be more preferred for non-Lamb wave and high-power devices and/or transmit filter components.

The one or more other acoustic wave devices that can be included in the acoustic wave system can include a cavity structure in accordance with any suitable principles and advantages disclosed herein. For example, a single acoustic wave system, such as an acoustic wave filter, can include two or more resonators and corresponding two or more cavity structures.

The support substrate 10 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, or the like. The support substrate 10 can have a relatively high impedance. An acoustic impedance of the support substrate 10 can be higher than an acoustic impedance of the piezoelectric layer 16. For instance, the support substrate 10 can have a higher acoustic impedance than an acoustic impedance of lithium niobate and a higher acoustic impedance than lithium tantalate.

The first layer 12 can be formed at, near, on, or with the support substrate 10. In some embodiments, the first layer 12 can be a trap-rich layer that can mitigate the parasitic surface conductivity of the support substrate 10. The trap-rich layer can be formed, for example, by forming the surface of the support substrate 10 with amorphous or polycrystalline silicon, by forming the surface of the support substrate 10 with porous silicon, or by introducing defects into the surface of the support substrate 10 via ion implantation, ion milling, or other methods. In some embodiments, the first layer 12 can improve the electrical characteristics of the SAW device 1a by increasing the depth and sharpness of the anti-resonance peak.

The second layer 14 can be positioned between the first layer 12 and the piezoelectric layer 16. The second layer 14 can be a dielectric layer, such as an oxide layer (e.g., silicon oxide (SiO₂) layer, or silicon nitride (SiN), or silicon oxynitride (SiON), or a multi-layer structure of two or more of these). The second layer 14 can enhance energy confinement and TCF tunability. In some embodiments, the second layer 14 can be a single crystal layer arranged to confine acoustic energy and lower a higher frequency spurious response. The second layer 14 can be referred to as a functional layer. In some embodiments, the second layer 14 can have a higher temperature coefficient of elasticity than the first layer 12.

The cavity structure 15a can confine acoustic energy between the IDT electrode 18 and the cavity structure 15a or in the piezoelectric layer 16. The cavity structure 15a can also reduce parasitic surface conductive effects on the surface of the support substrate 10, in some applications. Accordingly, the cavity structure 15a can contribute to improving nonlinearity.

The piezoelectric layer 16 can include lithium tantalate (LT). For example, the piezoelectric layer 16 can be an LT layer having a cut angle of 20° (20° Y-cut X-propagation LT) or a cut angle of 60° (60° Y-cut X-propagation LT). For example, the piezoelectric layer 16 can be 20±10° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 16. For example, the piezoelectric layer 16 can be an LN layer having a cut angle of about 118° (118° Y-cut X-propagation LN) or more or a cut angle of about 132° (132° Y-cut X-propagation LN) or less. For example, the piezoelectric layer 16 can be 125±20° Y-cut LN, 125±15° Y-cut LN, 125±10° Y-cut LN, or 125±5° Y-cut LN. In some embodiments, use of the LN layer in the piezoelectric layer 16 can provide an improved coupling coefficient.

The IDT electrode 18 can include any suitable material(s). The IDT electrode 18 may include one or more metals, such as aluminum (Al), copper (Cu), magnesium (Mg), titanium (Ti), tungsten (W), molybdenum (Mo), etc. The IDT electrode 18 may include alloys, such as AlMgCu, AlCu, etc. In some embodiments, the IDT electrode 18 can have a multi-layer IDT electrode that includes more than two layers. For example, the IDT electrode 18 can include first and second layers. The first layer can include molybdenum (Mo) and the second layer can include aluminum (Al) in certain embodiments.

The cavity structure 15a is an example of a periodically patterned cavity structure and has cavities aligned with the fingers of the IDT electrode 18. In some other embodiments, a periodically patterned cavity structure can be aligned with gaps between the fingers of the IDT electrode 18 (see FIG. 1B). In some embodiments, a cavity structure can include a single cavity (see FIG. 1C) or a non-periodically patterned cavity structure (see FIG. 1D).

FIG. 1B is a schematic cross-sectional side view of a SAW device 1b according to an embodiment. Unless otherwise noted, components of FIG. 1B can be the same as or generally similar to the like components disclosed herein, such as those shown in FIG. 1A. The SAW device 1b is generally similar to the SAW device 1a of FIG. 1A, but in the SAW device 1b, the cavities of the cavity structure 15b are aligned with gaps between the fingers of the IDT electrode 18.

In some embodiments, a width of a cavity in the cavity structure 15b can be the same as or generally similar to a width of a gap between the IDT electrode 18. The number of cavities in the cavity structure 15b can be equal to, greater than, or less than the number of the gaps between the fingers in the IDT electrode 18. In some embodiments, an area of the cavity structure 15b can be greater than an area of the IDT electrode 18.

FIG. 1C is a schematic cross-sectional side view of a SAW device 1c according to an embodiment. Unless otherwise noted, components of FIG. 1C can be the same as or generally similar to the like components disclosed herein, such as those shown in FIGS. 1A and 1B. The SAW device 1c is generally similar to the SAW devices 1a, 1b of FIGS. 1A and 1B, but in the SAW device 1c, the cavity structure 15c includes a cavity that covers an area of the IDT electrode 18. While the patterned cavity structures (e.g., the cavity structures 15a, 15b) can provide a more reliable mechanical ruggedness and a better heat path than a single large cavity (e.g., the cavity structure 15c), the cavity structure 15c may confine the acoustic energy between the cavity structure 15c and the IDT electrode 18 more effectively. Therefore, there can be a tradeoff between the patterned cavity structure and the single large cavity. The pattern of the patterned cavity structure can be adjusted to accommodate for the tradeoff. The different types of cavity structures can be implemented in different acoustic devices. For example, the patterned cavity structure can be more suitable for certain devices (e.g., high-power applications), and the single large cavity can be more suitable for other devices.

FIG. 1D is a schematic cross-sectional side view of a SAW device 1d according to an embodiment. Unless otherwise noted, components of FIG. 1D can be the same as or generally similar to the like components disclosed herein, such as those shown in FIGS. 1A to 1C. The SAW device 1d is generally similar to the SAW devices 1a, 1b, 1c of FIGS. 1A to 1C, but in the SAW device 1d, the cavities of the cavity structure 15d are non-periodically patterned or arranged. Non-periodically arranged cavities can contribute to spreading higher harmonics and overtone, which can reduce non-linearity effects on the higher harmonics.

A non-periodically patterned cavity structure can include an aperiodically patterned cavity structure and a randomly patterned cavity structure. Non-periodically patterned structures lack a repeating, periodic sequence, but may still follow a deterministic arrangement, such as quasi-crystalline patterns or sequences governed by mathematical rules. Aperiodically patterned structures are a subset of non-periodic patterns where the arrangement does not exhibit periodic repetition, but there is often an underlying rule or order. Randomly patterned structures, on the other hand, lack any discernible order or predictable arrangement, with patterns generated entirely by chance.

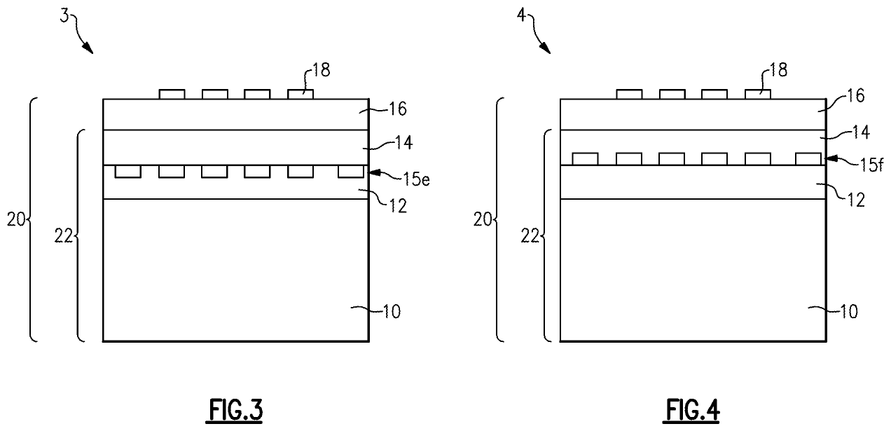

Cavity structures disclosed herein can be positioned in any suitable location in a support structure of an MPS-SAW device as shown in FIG. 2. For example, a cavity structure can be positioned in a support substrate as shown in FIGS. 1A-1D, in an intermediate structure between the support substrate and the piezoelectric layer as shown in FIGS. 3 and 4.

FIG. 2 is a schematic cross-sectional side view of a SAW device 2 according to an embodiment. Unless otherwise noted, components of FIG. 2 can be the same as or generally similar to the like components disclosed herein, such as those shown in FIGS. 1A to 1D. The SAW device 2 can include a multi-layer piezoelectric substrate 20 that includes a piezoelectric layer 16 and a support structure 22, a cavity structure 15 in the support structure 22, an interdigital transducer electrode 18 in electrical communication with the piezoelectric layer 16. The support structure 22 can include one or more layers as disclosed herein. The cavity structure 15 can include one or more cavities arranged in any suitable manner as disclosed herein. The cavity structures 15a-15f disclosed herein are examples of the cavity structure 15.

FIG. 3 is a schematic cross-sectional side view of a SAW device 3 according to an embodiment. Unless otherwise noted, components of FIG. 3 can be the same as or generally similar to the like components disclosed herein, such as those shown in FIGS. 1A to 2. The SAW device 3 is generally similar to the SAW device 1a of FIG. 1A, but in the SAW device 3, the cavity structure 15e is positioned in the first layer 12 (e.g., a trap-rich layer).

FIG. 4 is a schematic cross-sectional side view of a SAW device 4 according to an embodiment. Unless otherwise noted, components of FIG. 4 can be the same as or generally similar to the like components disclosed herein, such as those shown in FIGS. 1A to 3. The SAW device 4 is generally similar to the SAW devices 1a, 3 of FIGS. 1A and 3, but in the SAW device 4, the cavity structure 15e is positioned in the second layer 14 (e.g., a functional layer).

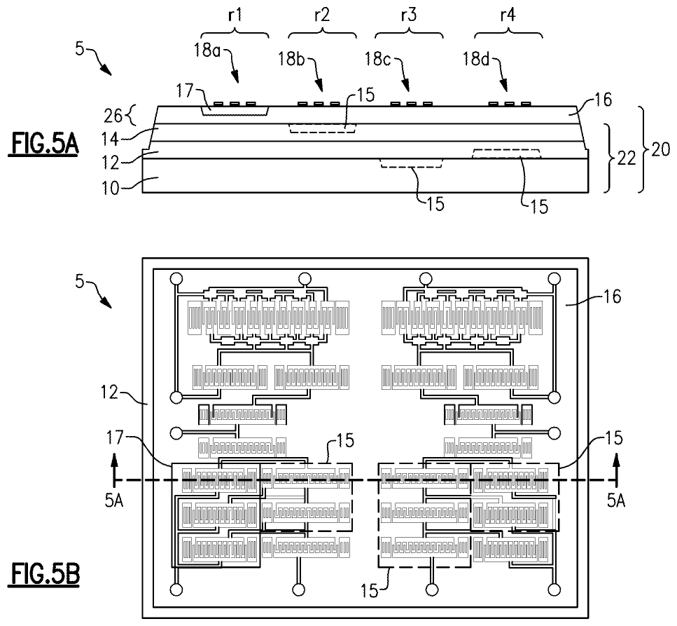

FIG. 5A is a schematic cross-sectional side view of a surface acoustic wave (SAW) device 5 according to an embodiment. FIG. 5B is a schematic top-plan view of the SAW device 5 of FIG. 5A. Unless otherwise noted, components of FIGS. 5A and 5B can be the same as or generally similar to the like components disclosed herein.

The SAW device 5 can include a support substrate 10, an intermediate structure including a first layer 12 and a second layer 14, cavity structures 15, a piezoelectric layer 16, an additional piezoelectric layer 17, and acoustic elements including first to fourth interdigital transducer (IDT) electrodes 18a, 18b, 18c, 18d. The first IDT electrode 18a is positioned in a first region r1, the second IDT electrode 18b is positioned in a second region r2, the third IDT electrode 18c is positioned in a third region r3, and the fourth IDT electrode 18d is positioned in a fourth region r4. The piezoelectric layer 16 and the additional piezoelectric layer 17 can together define a piezoelectric structure 26. In FIG. 5A, the number of fingers of the acoustic elements is reduced for illustration purposes.

The additional piezoelectric layer 17 in the first region r1 can include the same material or a different material as the piezoelectric layer 16. For example, the additional piezoelectric layer 17 can include an LT layer or an LN layer. The piezoelectric layer 16 can be referred to as a first piezoelectric layer and the additional piezoelectric layer 17 can be referred to as a second piezoelectric layer. When the piezoelectric layer 16 and the additional piezoelectric layer 17 have the same material, the piezoelectric layer 16 and the associated piezoelectric layer 17 may have a unitary structure. When the piezoelectric layer 16 and the additional piezoelectric layer 17 have different materials, the piezoelectric layer 16 and the associated piezoelectric layer 17 can be separate layers with an interface therebetween.

In the second region r2, the cavity structure 15 is included in the second layer 14 of the support structure 22. In the third region r3, the cavity structure 15 is included in the support substrate 10 of the support structure 22. In the fourth region r4, the cavity structure 15 is included in the first layer 12 of the support structure 22.

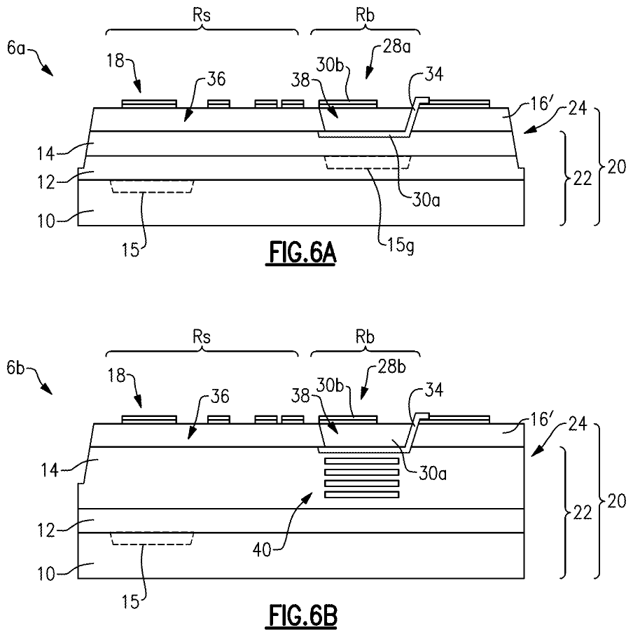

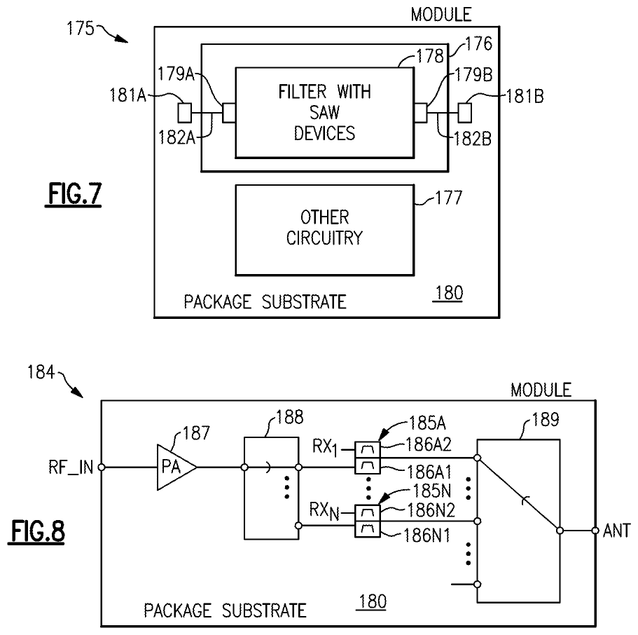

Although FIGS. 1A-5B illustrate SAW devices that include the cavity structures, there can be one or more BAW devices included in an acoustic wave system that implements the cavity structures disclosed herein. In some embodiments, a cavity structure can be provided with a BAW device as an acoustic reflector (see FIG. 6A). In some embodiments, a BAW device can be included in an acoustic wave system that includes a SAW device with a cavity structure (see FIGS. 6A and 6B).

FIG. 6A is a schematic cross-sectional side view of an acoustic wave device 6a according to an embodiment. Unless otherwise noted, components of FIG. 6A can be the same as or generally similar to the like components disclosed herein. The acoustic wave device 6a can include a SAW region Rs and a BAW region Rb. A BAW device 28a can be formed in the BAW region Rb.

The BAW device 28a can include a first electrode 30a, a second electrode 30b, and a cavity structure 15g as an acoustic reflector. A conductive layer 34 can be provided to electrically connect the first electrode 30a to a conductive structure or to another resonator in the acoustic wave device 6a.

The piezoelectric layer 16′ can include a first portion that includes a first piezoelectric material 36 and a second portion that includes a second piezoelectric material 38. The first portion can be in the SAW region Rs and the second portion can be in the BAW region Rb. The first piezoelectric material 36 can be a material suitable for a SAW device and the second piezoelectric material 38 can be a material suitable for a BAW device. For example, the first piezoelectric material 36 can be LN or LT. The second piezoelectric material 38 can include a material such as, but not limited to, aluminum nitride (AlN), zinc oxide (ZnO), or lead zirconium titanate (PZT). In certain applications, the second piezoelectric material 38 can be an AlN layer. The second piezoelectric material 38 can be doped or undoped. For example, an AlN-based piezoelectric layer can be doped with any suitable dopant, such as scandium (Sc), chromium (Cr), magnesium (Mg), sulfur(S), yttrium (Y), silicon (Si), germanium (Ge), oxygen (O), hafnium (Hf), zirconium (Zr), titanium (Ti), or the like. In certain applications, the second piezoelectric material 38 can be an AlN-based layer doped with Sc. Doping the second piezoelectric material 38 can adjust the resonant frequency. Doping the second piezoelectric material 38 can increase the electromechanical coupling coefficient (kt2) of the BAW device 28a.

FIG. 6B is a schematic cross-sectional side view of an acoustic wave device 6b according to an embodiment. Unless otherwise noted, components of FIG. 6B can be the same as or generally similar to the like components disclosed herein. The acoustic wave device 6b can include a solid acoustic wave mirror 40. The solid acoustic wave mirror 40 includes an acoustic Bragg reflector. The illustrated acoustic Bragg reflector can include alternating low impedance layers and high impedance layers. In some embodiments, the material of the second layer 14 can be the low impedance layer, and additional layers can be provided as the high impedance layer. As an example, the Bragg reflectors can include alternating silicon dioxide layers as low impedance layers and tungsten layers as high impedance layers. Any other suitable features of an SMR can alternatively or additionally be implemented.

The acoustic wave devices 6a, 6b shown in FIGS. 6A and 6B are examples of hybrid acoustic systems. The hybrid acoustic wave systems disclosed herein can implement one or more SAW devices and one or more BAW devices without significantly increasing the overall size of the system. Any suitable combination(s) of the features disclosed herein can be implemented in a single system. For example, two or more features of the cavity structures disclosed herein can be combined in a single acoustic wave system.

The acoustic wave devices disclosed herein can be implemented in acoustic wave filters. In certain applications, the acoustic wave filters can be band pass filters arranged to pass a radio frequency band and attenuate frequencies outside of the radio frequency band. Two or more acoustic wave filters can be coupled together at a common node and arranged as a multiplexer, such as a duplexer.

FIG. 7 is a schematic diagram of a radio frequency module 175 that includes a surface acoustic wave component 176 according to an embodiment. The illustrated radio frequency module 175 includes the SAW component 176 and other circuitry 177. The SAW component 176 can include one or more SAW devices with any suitable combination of features of the SAW devices disclosed herein. The SAW component 176 can include a SAW die that includes one or more MMS filters and/or one or more SAW resonators.

The SAW component 176 shown in FIG. 7 includes a filter 178 and terminals 179A and 179B. The filter 178 includes SAW devices. One or more of the SAW devices can be implemented in accordance with any suitable principles and advantages disclosed herein. In some other embodiments, the filter 178 can include one or more BAW devices. One or more SAW devices and one or more BAW devices can be implemented in the filter 178 in accordance with any suitable principles and advantages disclosed herein.

The terminals 179A and 179B can serve, for example, as an input contact and an output contact. The SAW component 176 and the other circuitry 177 are on a common packaging substrate 180 in FIG. 7. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

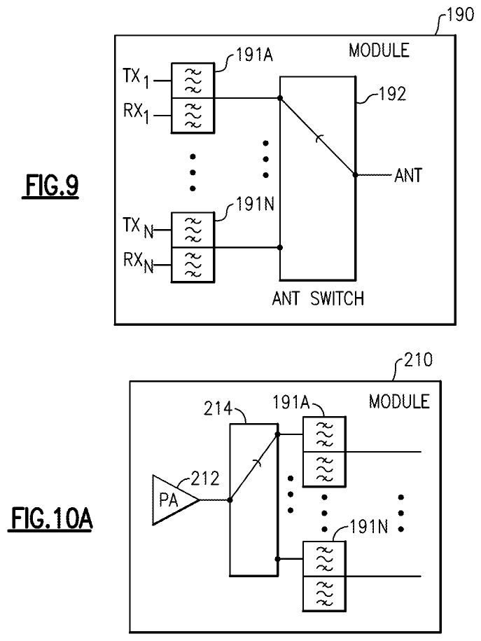

FIG. 8 is a schematic diagram of a radio frequency module 184 that includes an acoustic wave device or system according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more acoustic wave devices in accordance with any suitable principles and advantages disclosed herein. Similarly, one or more of the receive filters 186A2 to 186N2 can include one or more acoustic wave devices in accordance with any suitable principles and advantages disclosed herein. Although FIG. 8 illustrates duplexers, any suitable principles and advantages disclosed herein can be implemented in other multiplexers (e.g., quadplexers, hexaplexers, octoplexers, etc.) and/or in switch-plexers and/or in standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

FIG. 9 is a schematic block diagram of a module 190 that includes duplexers 191A to 191N and an antenna switch 192. One or more filters of the duplexers 191A to 191N can include any suitable number of acoustic wave devices in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190. MMS filters disclosed herein can be implemented in receive filters of one or more of the duplexers 191A to 191N, for example.

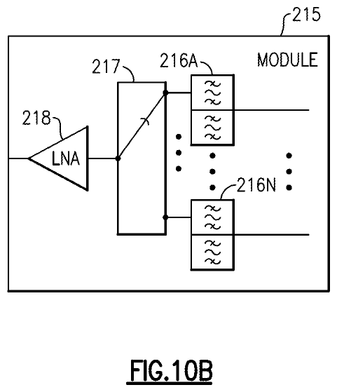

FIG. 10A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of acoustic wave devices in accordance with any suitable principles and advantages discussed herein. Any suitable number of duplexers 191A to 191N can be implemented.

FIG. 10B is a schematic block diagram of a module 215 that includes filters 216A to 216N, a radio frequency switch 217, and a low noise amplifier 218 according to an embodiment. One or more filters of the filters 216A to 216N can include any suitable number of MMS filters and/or acoustic wave resonators in accordance with any suitable principles and advantages disclosed herein. Any suitable number of filters 216A to 216N can be implemented. The illustrated filters 216A to 216N are receive filters. In some embodiments (not illustrated), one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments (not illustrated), a plurality of low noise amplifiers can be implemented. The module 215 can include diversity receive features in certain applications.

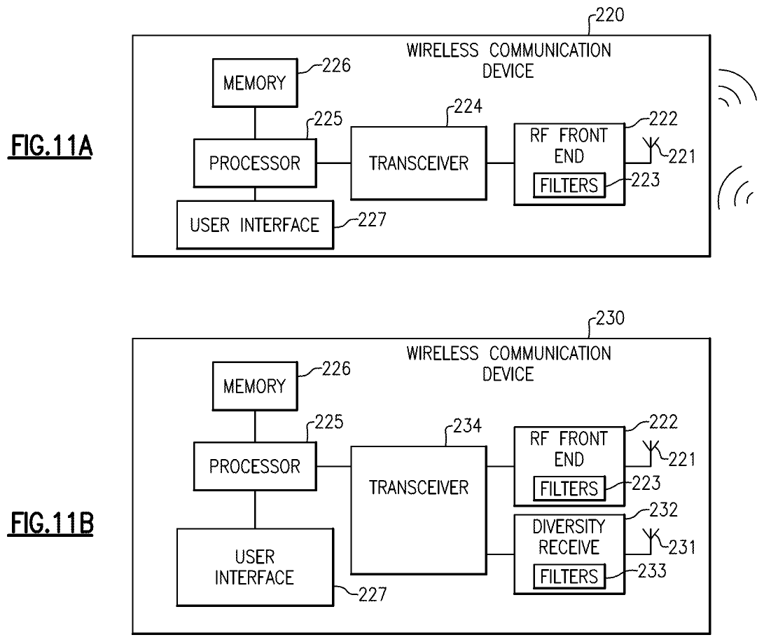

FIG. 11A is a schematic diagram of a wireless communication device 220 that includes filters 223 in a radio frequency front end 222 according to an embodiment. The filters 223 can include one or more acoustic wave devices in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include acoustic wave devices that include any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 11B is a schematic diagram of a wireless communication device 230 that includes filters 223 in a radio frequency front end 222 and second filters 233 in a diversity receive module 232. The wireless communication device 230 is like the wireless communication device 220 of FIG. 11A, except that the wireless communication device 230 also includes diversity receive features. As illustrated in FIG. 11B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more acoustic wave devices that include any suitable combination of features discussed with reference to any embodiments discussed above. The diversity module 232 and the radio frequency front end 222 can together be considered part of a radio frequency front end.

Although embodiments disclosed herein relate to surface acoustic wave filters and/or resonators, any suitable principles and advantages disclosed herein can be applied to other types of acoustic wave devices that include an IDT electrode, such as Lamb wave devices and/or boundary wave devices. For example, any suitable combination of features of the acoustic velocity adjustment structures disclosed herein can be applied to a Lamb wave device and/or a boundary wave device.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A surface acoustic wave device comprising:
a support substrate having a cavity;
a piezoelectric layer over the support substrate; and
an interdigital transducer electrode in electrical communication with the piezoelectric layer and being positioned over the cavity.

2. The surface acoustic wave device of claim 1 wherein an area of the cavity is greater than an area of the interdigital transducer electrode.

3. The surface acoustic wave device of claim 1 wherein the cavity is one of patterned cavities.

4. The surface acoustic wave device of claim 3 wherein the patterned cavities are aligned with fingers of the interdigital transducer electrode.

5. The surface acoustic wave device of claim 3 wherein the patterned cavities are aligned with gaps between fingers of the interdigital transducer electrode.

6. The surface acoustic wave device of claim 3 wherein the patterned cavities have a non-periodic pattern.

7. The surface acoustic wave device of claim 6 wherein the patterned cavities have an aperiodic pattern.

8. The surface acoustic wave device of claim 1 wherein the cavity includes an air cavity.

9. The surface acoustic wave device of claim 1 wherein the cavity is at least partially filled with a dielectric material.

10. The surface acoustic wave device of claim 1 further comprising a second interdigital transducer electrode in electrical communication with the piezoelectric layer.

11. The surface acoustic wave device of claim 10 further comprising a second cavity, wherein the second interdigital transducer electrode is positioned over the second cavity.

12. The surface acoustic wave device of claim 11 wherein the second cavity is formed in the support substrate.

13. The surface acoustic wave device of claim 1 further comprising an intermediate structure between the support substrate and the piezoelectric layer.

14. A surface acoustic wave device comprising:
a multi-layer piezoelectric substrate including a support substrate, a piezoelectric layer over the support substrate, and an intermediate structure between the support substrate and the piezoelectric layer, the support substrate having an air cavity; and
an interdigital transducer electrode in electrical communication with the piezoelectric layer and being positioned over the air cavity.

15. The surface acoustic wave device of claim 14 wherein the intermediate structure includes a trap-rich layer and a dielectric layer.

16. An acoustic wave filter comprising:
a support substrate having a cavity;
a piezoelectric layer over the support substrate;
a first acoustic wave element including an interdigital transducer electrode in electrical communication with the piezoelectric layer and being positioned over the cavity; and
a second acoustic wave element electrically coupled to the first acoustic wave element.

17. The acoustic wave filter of claim 16 wherein the second acoustic wave element is a surface acoustic wave resonator.

18. The acoustic wave filter of claim 16 wherein the second acoustic wave element is a bulk acoustic wave resonator.

19. The acoustic wave filter of claim 16 further comprising an intermediate structure between the support substrate and the piezoelectric layer.

20. The acoustic wave filter of claim 19 wherein the intermediate structure includes a second cavity.
